(19) United States
(12) Patent Application Publication
(10) Pub. No.: US 2009/0134529 A1
(43) Pub. Date: May 28, 2009

(54) CIRCUIT BOARD MODULE, ELECTRIC DEVICE, AND METHOD FOR PRODUCING CIRCUIT BOARD MODULE

(75) Inventors: Norihiro Ishii, Akishima-shi (JP); Kuniyasu Hosoda, Hanno-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/203,823

(22) Filed: Sep. 3, 2008

(30) Foreign Application Priority Data
Nov. 28, 2007 (JP) 2007-307915

(51) Int. Cl. H01L 23/52; H01L 21/00

(52) U.S. Cl. 257/779; 438/121; 257/E23.141; 257/E21.001

(57) ABSTRACT

A circuit board module includes: a printed wiring board that is provided with a plurality of solder bonding pads; a semiconductor package that is provided with a plurality of solder bonding portions on a back face thereof to be mounted on the printed wiring board by soldering the solder bonding portions onto the respective solder bonding pads on the printed wiring board; a plurality of reinforcement pads that are provided on the printed wiring board at positions along peripheral edges of the semiconductor package, each of the reinforcement pads having a solder coated layer formed thereon; and a plurality of reinforcing adhesive agents that are disposed on each of the reinforcement pads to adhere the semiconductor package to the reinforcement pads.

### CROSS-REFERENCE TO RELATED APPLICATIONS

This application is based upon and claims the benefit of priority from Japanese Patent Application No. 2007-307915, filed on Nov. 28, 2007, the entire content of which are incorporated herein by reference.

### BACKGROUND

1. Field

One embodiment of the present invention relates to a circuit board module on which a semiconductor package having a plurality of solder bonding portions being arranged on the back face of the package is mounted.

2. Description of the Related Art

In an electronic device such as a personal computer, a circuit board module, on which a large semiconductor package of about several ten millimeters square that forms a CPU or peripheral circuits thereof is mounted, is accommodated in a case as a main component.

The circuit board module of this kind used in the electronic device requires to protect a mounting surface of the semiconductor package from a warpage or deformation of a circuit board module and a stress exerted by an externally applied impact or vibration.

As a means for protecting the solder bonding portions of parts mounted on the board from the above-described stress, a method for mounting electronic parts is known in a compact semiconductor chip of about several millimeters square mounted on the board by a face-down bonding method, that a part between the board and the semiconductor chip is impregnated with an under-fill material to fill a gap between the board and the semiconductor chip with the under-fill material so that the semiconductor chip is fixed to the board. A reinforcing unit by the under-fill material is widely applied to the compact semiconductor chip of several millimeters square or so. However, when this reinforcing unit is applied to the circuit board module on which the large semiconductor package as mentioned above is mounted, a problem arises that a reinforcing material embedded between the semiconductor package and the board as the under-fill material repeats a thermal expansion due to a self-heat generation caused by a circuit operation of the semiconductor package so that an excessive stress is exerted on the solder bonding portions due to the thermal expansion. Especially, in the circuit board module on which the large semiconductor package having the solder bonding portions arranged on the back face of the package, for example, BGA, LGA or the like is mounted, the stress is concentrated to the corner parts of the package of a rectangular shape. Thus, the circuits of the solder bonding portions are broken. As coefficient of thermal expansion of the reinforcing material embedded as the under-fill material is more different from that of the semiconductor package or the board, this problem appears the more outstandingly. Further, since the entire part of the mounting surface of the large semiconductor package is bonded to the board, a problem arises that a reworking operation is difficult.

In the circuit board module on which the large semiconductor package, such as the BGA and the LGA, is mounted, there is usually used a technique for reinforcing the solder bonding portions that specific electrodes which can be integrated in an integrating land of a wiring board are collected in a position where the stress of joint parts to the printed wiring board is liable to be generated to provide the integrating land. Further, as another technique for reinforcement, there is a technique to improve a physical bond strength of the BGA to the wiring board by using a reinforcing pin.

Examples of the techniques described above are disclosed in JP-A-2001-177226 and in JP-A-2000-277884.

However, since the above-described techniques require a special structure of an electrode arrangement, the technique is low in its generalization. Further, in the technique, since the number of processes and a cost need to be increased due to the increase of special parts and the increase of parts, a problem arises in view of practicality.

### SUMMARY

One of objects of the present invention is to provide a circuit board module that reduces an influence of an external stress to solder bonding portions to avoid the deficiencies of the connections of the solder bonding portions and can be easily reworked.

According to a first aspect of the present invention, there is provided a circuit board module including: a printed wiring board that is provided with a plurality of solder bonding pads; a semiconductor package that is provided with a plurality of solder bonding portions on a back face thereof to be mounted on the printed wiring board by soldering the solder bonding portions onto the respective solder bonding pads on the printed wiring board; a plurality of reinforcement pads that are provided on the printed wiring board at positions along peripheral edges of the semiconductor package, each of the reinforcement pads having a solder coated layer formed thereon; and a plurality of reinforcing adhesive agents that are disposed on each of the reinforcement pads to adhere the semiconductor package to the reinforcement pads.

According to a second aspect of the present invention, there is provided a method for producing a circuit board module having a semiconductor package mounted on a printed wiring board that is provided with a plurality of solder bonding pads, the method including: supplying the printed wiring board to a component mounting line, the printed wiring board having a plurality of reinforcement pads at positions along peripheral edges of a package mounting surface on which the semiconductor package is mounted; printing solder paste on each of the solder bonding pads and the reinforcement pads of the printed wiring board supplied to the component mounting line; disposing thermosetting adhesive agents on each of the reinforcement pads on which the solder paste is printed; mounting the semiconductor package having a plurality of solder bonding portions on a back face thereof onto the package mounting surface of the printed wiring board in a state where the thermosetting adhesive agent adheres to the semiconductor package; and thermally treating the solder bonding pads and the reinforcement pads to solder the solder bonding pads to the respective solder bonding portions of the semiconductor package while forming a solder coated layer on the reinforcement pads and solidifying the thermosetting adhesive agent to adhere the semiconductor package to the reinforcement pads.

According to a third aspect of the present invention, there is provided an electronic device including: a main body; and a circuit board module that is accommodated in the main body, wherein the circuit board module includes: a printed wiring board that is provided with a plurality of solder bonding pads; a semiconductor package that is provided with a plurality of solder bonding portions on a back face thereof to be mounted on the printed wiring board by soldering the solder bonding portions onto the respective solder bonding pads on the printed wiring board; a plurality of reinforcement pads that are provided on the printed wiring board at positions along peripheral edges of the semiconductor package, each of the reinforcement pads having a solder coated layer formed thereon; and a plurality of reinforcing adhesive agents that are disposed on each of the reinforcement pads to adhere the semiconductor package to the reinforcement pads.

### BRIEF DESCRIPTION OF THE SEVERAL VIEWS OF THE DRAWINGS

A general configuration that implements the various feature of the invention will now be described with reference to the drawings. The drawings and the associated descriptions are provided to illustrate embodiments of the invention and not to limit the scope of the invention.

FIG. 1 is a side view showing a structure of a circuit board module according to a first embodiment of the present invention.

FIG. 2 is a plan view showing the structure of the circuit board module according to the first embodiment.

FIG. 3 is a plan view showing a first modified example of a reinforcing part provided in the circuit board module according to the first embodiment.

FIG. 4 is a plan view showing a second modified example of a reinforcing part provided in the circuit board module according to the first embodiment.

FIG. 5 is a plan view showing a third modified example of a reinforcing part provided in the circuit board module according to the first embodiment.

FIG. 6 is a flowchart showing a first production process of the circuit board module according to the first embodiment.

FIG. 7 is a flowchart showing a first production process of the circuit board module according to the first embodiment.

FIG. 8 is a process explaining diagram for explaining the first production process of the circuit board module according to the first embodiment.

FIG. 9 is a process explaining diagram for explaining the first production process of the circuit board module according to the first embodiment.

FIG. 10 is a process explaining diagram for explaining the first production process of the circuit board module according to the first embodiment.

FIG. 11 is a process explaining diagram for explaining the first production process of the circuit board module according to the first embodiment.

FIG. 12 is a flowchart showing a second production process of the circuit board module according to the first embodiment.

FIG. 13 is a process explaining diagram for explaining the second production process of the circuit board module according to the first embodiment.

FIG. 14 is a process explaining diagram for explaining the second production process of the circuit board module according to the first embodiment.

FIG. 15 is a process explaining diagram for explaining the second production process of the circuit board module according to the first embodiment.

FIG. 16 is a process explaining diagram for explaining the second production process of the circuit board module according to the first embodiment.

FIG. 17 is a diagram showing the structure of an electronic device according to a second embodiment of the present invention.

FIG. 18 is a side view showing a structure of a circuit board module according to a modification of the first embodiment.

### DETAILED DESCRIPTION

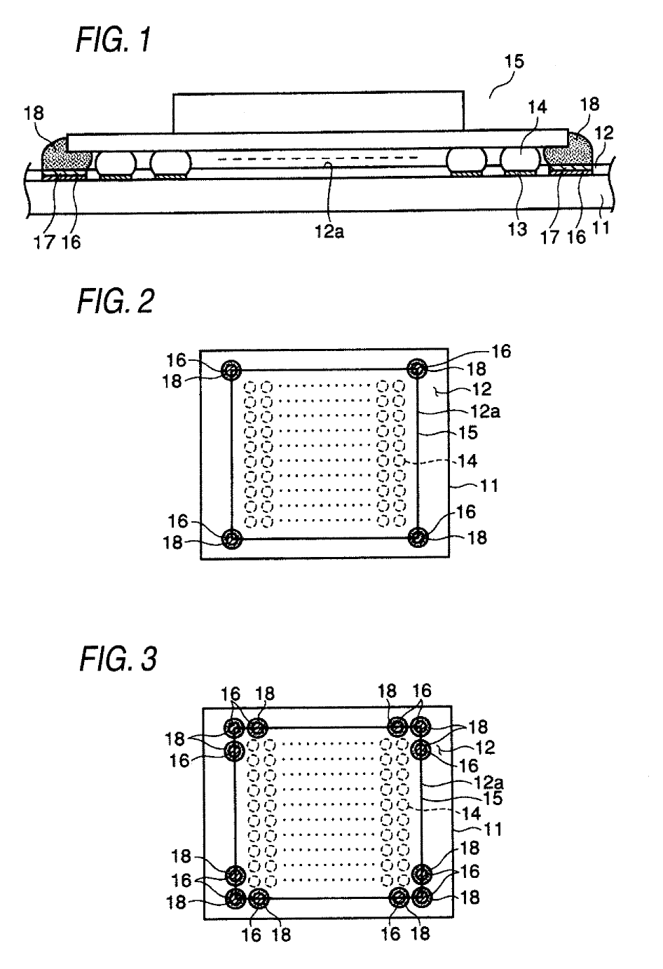

A detailed explanation will be given of an embodiment of the present invention with reference to the accompanying drawings. A structure of a circuit board module according to a first embodiment of the present invention is shown in FIGS. 1 and 2. FIG. 1 is a side view of main parts and FIG. 2 is a plan view of the main parts.

As shown in FIGS. 1 and 2, the circuit board module according to the first embodiment includes: a printed wiring board 11; a semiconductor package 15 having a plurality of solder bonding portions 14 arranged in the form of a matrix on the back face of the package and mounted on the printed wiring board 11 by soldering respectively the solder bonding portions 14; a plurality of reinforcement pads 16 provided on a plurality of parts along the peripheral edge of a mounting surface part of the printed wiring board 11 on which the semiconductor package 15 is mounted and having solder coated layers 17 applied to surfaces; and reinforcing adhesive agents 18 that fix the plurality of reinforcement pads 16 to the semiconductor package 15 at the plurality of parts to locally reinforce the solder bonding portions 14 at the plurality of parts.

In the embodiment, as the semiconductor package 15, a ball grid array package (BGA package) is shown, as an example, in which the plurality of solder bonding portions 14 arranged in the matrix form are respectively solder balls.

In a pattern forming surface 12 of the circuit board module 11, on a BGA parts mounting surface part 12a designed to be patterned by designating the BGA package 15 as an object to be mounted, a plurality of solder bonding pads 13 corresponding to the plurality of solder bonding portions 14 provided on the BGA package 15 are patterned and formed in a matrix shape. The BGA parts mounting surface 12a is formed so as to have a surface corresponding to a plane form of the BGA package 15 to be mounted.

At the plurality of parts along the peripheral edge of the BGA parts mounting surface part 12a, the plurality of reinforcement pads 16 are arranged. In the embodiment, at the corner parts of the BGA parts mounting surface part 12a, the reinforcement pads 16 are respectively provided with prescribed spaces from the solder bonding pads 13. On the surfaces of the reinforcement pads 16, the solder coated layers 17 are formed for easily performing a reworking process. The solder coated layers 17 are formed to coat the reinforcement pads 16 therewith in a reflow process for soldering and bonding the BGA package 15.

On the reinforcement pads 16, the reinforcing adhesive agents 18 are supplied for locally reinforcing the solder bonding portions 14 at the plurality of parts through the solder coated layers 17 or cream solders that form the solder coated layers 17 afterward. A thermosetting adhesive agent may be applied to the reinforcing adhesive agents 18. The reinforcing adhesive agents 18 are supplied to the reinforcement pads 16 to which the solder coated layers 17 are applied by a prescribed amount as a unit for filling therewith parts between the reinforcement pads 16 and the peripheral edge of the BGA package 15. Thus, the reinforcement pads 16 are fixed and bonded to the BGA package 15 to each other by the adhesive reinforcing agents 18. Each of the solder coated layers 17 may be entirely provided on a top face of the respective reinforcement pads 16 as shown in FIG. 1, or may be partially provided on the top face of the respective reinforcement pads 16 as shown in FIG. 18. As shown in FIG. 18, each of the solder coated layers 17 may be formed on each of the reinforcement pads 16 to have an area smaller than that of the respective reinforcement pads 16, and the reinforcing adhesive agents 18 are disposed on each of the reinforcement pads 16 to cover side edges of each of the solder coated layers 17. According to the configuration shown in FIG. 18, the BGA package 15 can be more securely fixed onto the circuit board module 11.

On the BGA parts mounting surface part 12a of the printed wiring board 11, the plurality of solder bonding portions 14 provided in the BGA package 15 are soldered and bonded to the plurality of solder bonding pads 13 provided in the BGA parts mounting surface part 12a so that the BGA package 15 is mounted on the BGA parts mounting surface part 12a of the printed wiring board 11.

In the reflow process that the BGA package 15 is soldered and bonded to the BGA parts mounting surface part, the solder coated layers 17 are formed on the reinforcement pads 16. Further, when the thermosetting adhesive agent is used for the reinforcing adhesive agents 18, the thermosetting adhesive agent that bonds the reinforcement pads 16 to the BGA package 15 to each other is solidified in the reflow process to locally fix and bond the BGA package 15 to the reinforcement pads 16.

Thus, in the corner parts of the BGA parts mounting surface part 12a respectively, the solder bonding portions 14 of the BGA package 15 are locally reinforced by the reinforcement pads 16 and the reinforcing adhesive agents 18.

Such an inconvenience can be avoided that the solder bonding portions 14 provided in the corner parts of the BGA package 15 are broken and brought into an insufficient connection owing to an externally applied stress by the above-described local reinforcing units. Further, the reworking process is easily realized by the local reinforcing units and fixing units through the solder coated layers 17. That is, in the reworking process for detaching the BGA package 15 from the BGA parts mounting surface part 12a of the printed wiring board 11, since the solder coated layers 17 are molten by a thermal treatment during the reworking process, the solder coated layers 17 serve as peeling surfaces. Thus, a work for 20 removing the adhesive agent is not necessary and the reworking process can be easily performed without breaking parts.

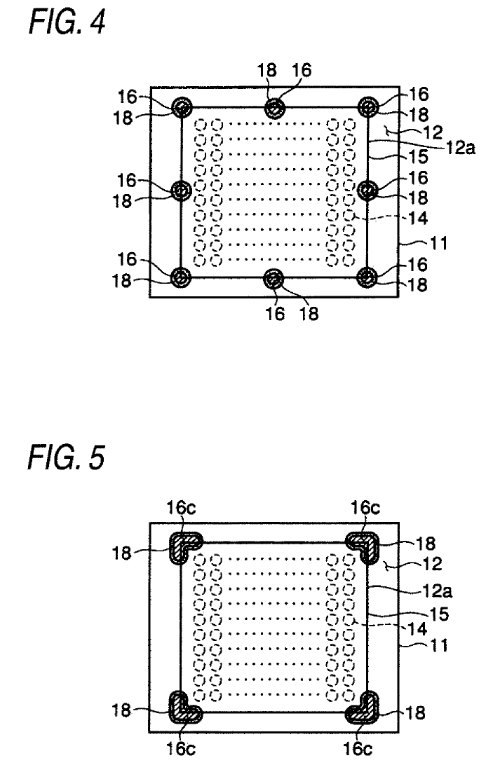

In the first embodiment shown in FIGS. 1 and 2, only at the corner parts (the corner parts of the BGA package 15) of the BGA parts mounting surface part 12a, reinforcing parts by the reinforcement pads 16 and the reinforcing adhesive agents 18 are locally provided. However, for example, as shown in FIG. 3, a multi-point reinforcing structure may be formed that reinforcing parts by the reinforcement pads 16 and the reinforcing adhesive agents 18 are provided in each corner part and one parts of two sides respectively in the vicinity of that corner included in the corner parts (the corner parts of the BGA package 15) of the BGA parts mounting surface part 12a. Otherwise, as shown in FIG. 4, a multi-point structure may be formed that reinforcing parts by the reinforcement pads 16 and the reinforcing adhesive agents 18 are respectively provided at the corner parts of the BGA parts mounting surface part 12a and parts of sides (for example, an intermediate point of each side). Otherwise, as shown in FIG. 5, a reinforcing structure may be formed that L-shaped reinforcement pads 16c are provided at the corner parts of the BGA parts mounting surface part 12a. The reinforcing structures by the multi-point reinforcing parts can achieve the same effects as those of the reinforcing structure shown in FIG. 2.

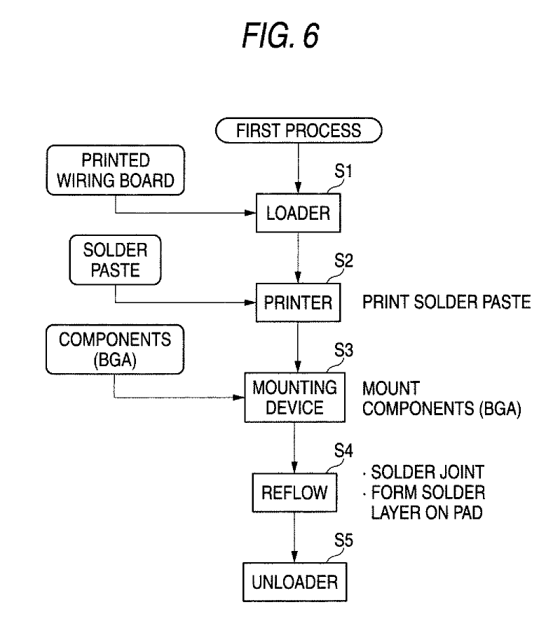

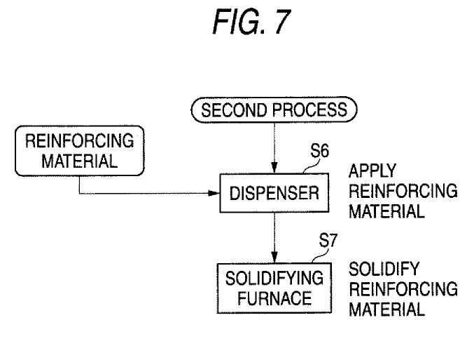

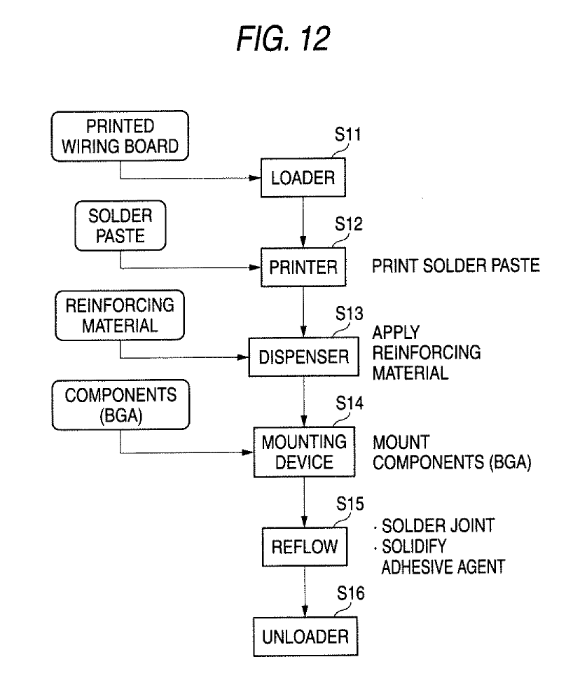

The circuit board module according to the first embodiment can be realized by either production processes shown by flowcharts in FIGS. 6 and 7 or a production process shown by a flowchart in FIG. 12. In the production processes shown in FIGS. 6 and 7, the reinforcing adhesive agents 18 are supplied and solidified in a separate process after the reflow process. Adhesive agents other than the thermosetting adhesive agent may be applied to the reinforcing adhesive agents 18. In the production process shown in FIG. 12, the thermosetting adhesive agent is applied to the reinforcing adhesive agents 18 so that a process for applying the solder coated layers 17 on the reinforcement pads 16 and a process for solidifying (hardening) the reinforcing adhesive agents (the thermosetting adhesive agent) 18 can be performed by the reflow process at a time.

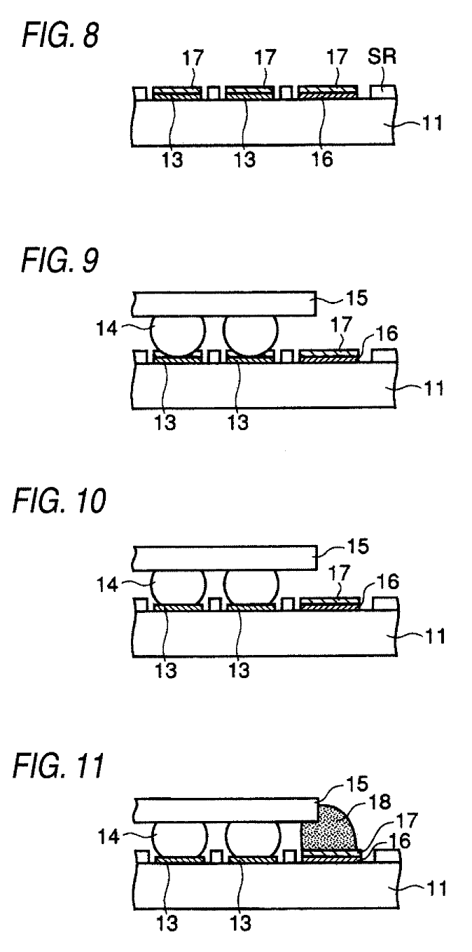

The production processes shown by the flowcharts in FIGS. 6 and 7 is explained by referring to process explaining diagrams shown in FIGS. 8 to 11.

In the production process (a first process) shown in FIG. 6, in step S1, the print wiring board as an object on which parts are mounted is supplied to a component mounting line to Here, the supplied printed wiring board is, as shown in FIG. 1, the printed wiring board 11 that has the plurality of solder bonding pads 13 respectively corresponding to the solder bonding portions 14 of the BGA package 15 patterned and formed on the BGA parts mounting surface part 12a designed to be patterned by designating the BGA package 15 as an object to be mounted.

In step S2, solder paste is printed respectively on the solder bonding portions of the printed wiring board 11 by a printer for printing the solder paste. Here, as shown in FIG. 8, the solder paste 17 is printed on the solder bonding pads 13 and the reinforcement pads 16 provided in the BGA parts mounting surface part 12a of the printed wiring board 11. Reference character SR shown in FIG. 8 designates a solder resist.

In step S3, parts are mounted on the parts mounting surface of the printed wiring board by a mounting device. Here, as shown in FIG. 9, the BGA package 15 is mounted on the BGA parts mounting surface part 12a of the printed wiring board 11.

In step S4, the reflow process of the mounted parts is performed in a reflow furnace. Here, as shown in FIG. 10, the solder bonding portions 14 of the BGA package 15 are respectively soldered and bonded to the plurality of solder bonding pads 13 provided in the BGA parts mounting surface part 12a and the solder coated layers 17 are formed on the reinforcement pads 16. The solder paste 17 applied on the reinforcement pads 16 in the step S2 is molten to coat the surfaces of the reinforcement pads 16 therewith so that the solder coated layers 17 are formed.

After the production process (the first process) shown in FIG. 6, the reinforcing adhesive agents are supplied and solidified in the production process (a second process) shown in FIG. 7.

In step S6, a reinforcing material serving as an adhesive agent is applied to the reinforcing parts of the parts mounting surface of the printed wiring board by a dispenser. Here, as shown in FIG. 11, the reinforcing adhesive agents 18 are supplied by a nozzle onto the reinforcement pads 16 provided at the corner parts of the BGA parts mounting surface part 12a and to which the solder coated layers 17 are applied. Thus, the adhesive agent serving as the reinforcing adhesive agents 18 is applied and spread over the corner parts of the BGA package 15 and the reinforcement pads 16.

In step S7, the adhesive agent applied in the step S6 is thermally treated in, for example, a solidifying furnace and solidified. By performing the process of the step S7, the reinforcing adhesive agents 18 supplied onto the reinforcement pads 16 and applied and spread over the corner parts of the BGA package 15 and the reinforcement pads 16 are solidified. Thus, the BGA package 15 is locally fixed to the reinforcement pads 16.

Since the circuit board module produced as described above has a reinforcing structure that the solder bonding portions 14 of the BGA package 15 are locally reinforced by the reinforcement pads 16 and the reinforcing adhesive agents 18 respectively in the corner parts of the BGA parts mounting surface part 12a, such an inconvenience can be avoided that the solder bonding portions 14 provided in the corner parts of the BGA package 15 are broken and brought into an insufficient connection due to an externally applied stress. Further, since the circuit board module has a reinforcing structure that locally reinforces the solder bonding portions 14 of the BGA package 15 by the reinforcement pads 16 to which the solder coated layers 17 are applied, the solder coated layers 17 serve as peeling surfaces in a heat treatment during the reworking process to make the reworking process easy.

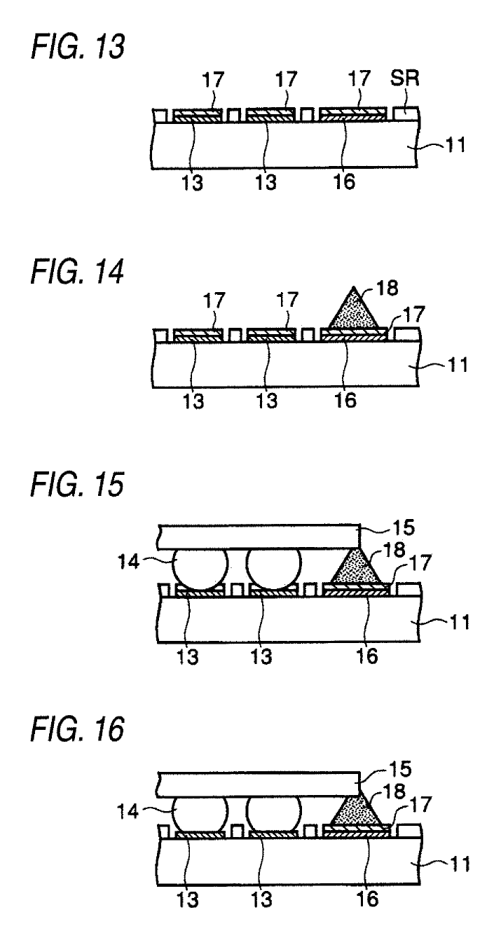

The production process shown by the flowchart in FIG. 12 will be described by referring to process explaining diagrams shown in FIGS. 13 to 16.

In the production process shown in FIG. 12, in step S11, the print wiring board as an object on which parts are mounted is supplied to a component mounting line. Here, the supplied printed wiring board is, as shown in FIG. 1, the printed wiring board 11 that has the plurality of solder bonding pads 13 respectively corresponding to the solder bonding portions 14 of the BGA package 15 patterned and formed on the BGA parts mounting surface part 12a designed to be patterned by designating the BGA package 15 as an object to be mounted.

In step S12, solder paste is printed respectively on the solder bonding portions of the printed wiring board 11 by a printer for printing the solder paste. Here, as shown in FIG. 13, the solder paste 17 is printed on the solder bonding pads 13 and the reinforcement pads 16 provided in the BGA parts mounting surface part 12a of the printed wiring board 11.

In step S13, a reinforcing material serving as an adhesive agent is applied to the reinforcing parts of the parts mounting surface of the printed wiring board by a dispenser. Here, as shown in FIG. 14, the thermosetting adhesive agent of a prescribed quantity serving as the reinforcing adhesive agents 18 is supplied by a nozzle onto the reinforcement pads 16 provided at the corner parts of the BGA parts mounting surface part 12a and to which the solder paste 17 is applied. The thermosetting adhesive agent 18 has such a viscosity as to be stuck to the BGA package 15 under a state that the thermosetting adhesive agent 18 heaps on the reinforcement pads 16 with a prescribed height (a height with which the thermosetting adhesive agent adheres to the mounted BGA package 15) and is locally dripped on the reinforcement pads 16.

In step S14, parts are mounted on the parts mounting surface of the printed wiring board by a mounting device. Here, as shown in FIG. 15, the BGA package 15 is mounted on the BGA parts mounting surface part 12a of the printed wiring board 11. When the BGA package 15 is mounted, the thermosetting adhesive agent 18 adheres to the mounted BGA package 15 so that the thermosetting adhesive agent 18 is spread over and embedded between the reinforcement pads 16 and the corner parts of the BGA package 15.

In step S15, the reflow process of the mounted parts is performed in a reflow furnace. Here, as shown in FIG. 16, the solder bonding portions 14 of the BGA package 15 are respectively soldered and bonded to the plurality of solder bonding pads 13 provided in the BGA parts mounting surface part 12a and the solder coated layers 17 are formed on the reinforcement pads 16 when the solder paste is molten. Further, the thermosetting adhesive agent 18 that bonds the reinforcement pads 16 to the BGA package 15 to each other is solidified to locally fix the BGA package 15 to the reinforcement pads 16.

Since the circuit board module produced in such a way has a reinforcing structure that the solder bonding portions 14 of the BGA package 15 are locally reinforced by the reinforcement pads 16 and the reinforcing adhesive agents 18 respectively in the corner parts of the BGA parts mounting surface part 12a, such an inconvenience can be avoided that the solder bonding portions 14 provided in the corner parts of the BGA package 15 are broken and brought into an insufficient connection due to an externally applied stress. Further, since the circuit board module has a reinforcing structure that locally reinforces the solder bonding portions 14 of the BGA package 15 by the reinforcement pads 16 to which the solder coated layers 17 are applied, the solder coated layers 17 serve as peeling surfaces in a heat treatment during the reworking process to make the reworking process easy. Further, in an ordinary parts mounting process, the increase of the number of processes is minimized so that the above-described local reinforcing structure can be realized.

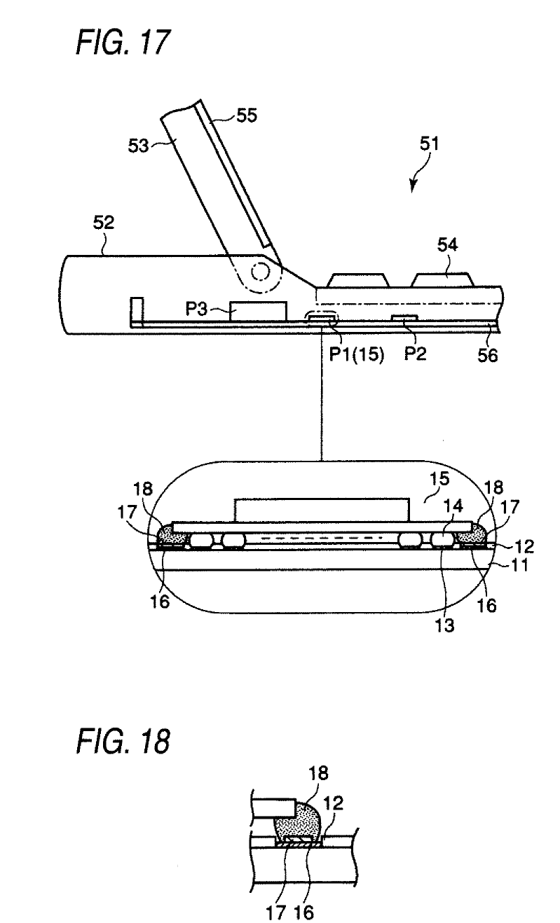

A second embodiment of the present invention is shown in FIG. 17.

The second embodiment forms an electronic device by using the circuit board module produced by the first embodiment. FIG. 17 shows an example in which the circuit board module according to the first embodiment is applied to a compact electronic device such as a handy type portable computer.

In FIG. 17, in a main body 52 of a portable computer 51, a case 53 of a display part is provided through a hinge mechanism so as to freely rotate. In the main body 52, a keyboard 54 serving as an operation input part is provided. In the case 53 of the display part, a display device 55 using, for example, a liquid crystal panel is provided.

Further, in the main body 52, a circuit board module (a mother board) 56 is provided that incorporates a control circuit for controlling input and output devices such as the above-described keyboard 54, the display device 55 or the like. The circuit board module 56 is realized by using the circuit board module of the first embodiment shown in FIGS. 1 and 2.

The circuit board module 56 includes: a printed wiring board 11; a BGA package 15 having a plurality of solder bonding portions 14 arranged in the form of a matrix on the back face of the package and mounted on the printed wiring board 11 by soldering respectively the solder bonding portions 14; a plurality of reinforcement pads 16 provided on a plurality of parts (for example, corner parts) along the peripheral edge of a mounting surface part of the printed wiring board 11 on which the BGA package 15 is mounted and having solder coated layers 17 applied to surfaces; and reinforcing adhesive agents 18 that fix the plurality of reinforcement pads 16 to the BRA package 15 at the plurality of parts to locally reinforce the solder bonding portions 14 at the plurality of parts.

In the circuit board module 56 configured as described above, since the solder bonding portions 14 of the BGA package 15 are locally reinforced by the reinforcement pads 16 and the reinforcing adhesive agents 18 respectively in the corner parts of the BGA parts mounting surface part 12a, such an inconvenience can be avoided that the solder bonding portions 14 provided in the corner parts of the BGA package 15 are broken and brought into an insufficient connection due to an externally applied stress. Further, since the solder coated layers 17 serve as peeling surfaces in a heat treatment during a reworking process in the reworking process by using local reinforcing units and fixing units through the solder coated layers 17, the reworking process is easily performed after parts is mounted.

In the above-described embodiments, the BGA parts is designated as an object to be reinforced, however, the present invention is not limited thereto. A similar reinforcing structure may be realized by designating other semiconductor package having outer connection electrodes arranged on a bottom surface as an object. Further, the forms, the arrangement or the like of the reinforcement pads are not limited to the above-described embodiments and various modifications and changes may be made within a scope without departing from the scope of the claimed invention.

According to the present invention, in the circuit board module on which the large semiconductor package such as the BGA, the LGA or the like is mounted, an influence of an external stress to the solder bonding portions can be reduced to avoid the deficiencies of the connections of the solder bonding portions and a reworking process can be easily performed.

What is claimed is:

1. A circuit board module comprising:
a printed wiring board that is provided with a plurality of solder bonding pads;
a semiconductor package that is provided with a plurality of solder bonding portions on a back face thereof to be mounted on the printed wiring board by soldering the solder bonding portions onto the respective solder bonding pads on the printed wiring board;
a plurality of reinforcement pads that are provided on the printed wiring board at positions along peripheral edges of the semiconductor package, each of the reinforcement pads having a solder coated layer formed thereon; and
a plurality of reinforcing adhesive agents that are disposed on each of the reinforcement pads to adhere the semiconductor package to the reinforcement pads.

2. The module according to claim 1, wherein the reinforcement pads are provided at positions corresponding to corner positions of the semiconductor package.

3. The module according to claim 1, wherein the reinforcement pads are provided at potions including a position corresponding to one of side edges of the semiconductor package.

4. The module according to claim 1, wherein the reinforcing adhesive agents are made of a thermosetting adhesive agent that solidify when the solder bonding portions are soldered onto the solder bonding pads.

5. The module according to claim 1, wherein the solder coated layers are formed on the reinforcement pads when the solder bonding portions are soldered.

6. The module according to claim 1, wherein the solder coated layer is formed on each of the reinforcement pads to have an area smaller than that of the respective reinforcement pads, and
wherein the reinforcing adhesive agents are disposed on each of the reinforcement pads to cover side edges of the solder coated layer.

7. A method for producing a circuit board module having a semiconductor package mounted on a printed wiring board that is provided with a plurality of solder bonding pads, the method comprising:
supplying the printed wiring board to a component mounting line, the printed wiring board having a plurality of reinforcement pads at positions along peripheral edges of a package mounting surface on which the semiconductor package is mounted;
printing solder paste on each of the solder bonding pads and the reinforcement pads of the printed wiring board supplied to the component mounting line;
disposing thermosetting adhesive agents on each of the reinforcement pads on which the solder paste is printed;
mounting the semiconductor package having a plurality of solder bonding portions on a back face thereof onto the package mounting surface of the printed wiring board in a state where the thermosetting adhesive agent adheres to the semiconductor package; and
thermally treating the solder bonding pads and the reinforcement pads to solder the solder bonding pads to the respective solder bonding portions of the semiconductor package while forming a solder coated layer on the reinforcement pads is and solidifying the thermosetting adhesive agent to adhere the semiconductor package to the reinforcement pads.

8. The method according to claim 7, wherein the reinforcement pads are provided at positions corresponding to corner positions of the semiconductor package.

9. An electronic device comprising:
a main body; and
a circuit board module that is accommodated in the main body,
wherein the circuit board module includes:
a printed wiring board that is provided with a plurality of solder bonding pads;
a semiconductor package that is provided with a plurality of solder bonding portions on a back face thereof to be mounted on the printed wiring board by soldering the solder bonding portions onto the respective solder bonding pads on the printed wiring board;
a plurality of reinforcement pads that are provided on the printed wiring board at positions along peripheral edges of the semiconductor package, each of the reinforcement pads having a solder coated layer formed thereon; and
a plurality of reinforcing adhesive agents that are disposed on each of the reinforcement pads to adhere the semiconductor package to the reinforcement pads.
